(19) United States
(12) Patent Application Publication
(10) Pub. No.: US 2026/0066036 A1
(43) Pub. Date: Mar. 5, 2026

(54) EFUSE MEMORY AND OPERATION METHOD THEREOF

(71) Applicant: Shanghai Huali Integrated Circuit Corporation, Shanghai (CN)

(72) Inventor: Ying YAN, Shanghai (CN)

(73) Assignee: Shanghai Huali Integrated Circuit Corporation, Shanghai (CN)

(21) Appl. No.: 19/187,401

(22) Filed: Apr. 23, 2025

(30) Foreign Application Priority Data
Aug. 30, 2024 (CN) 202411216062.6

(51) Int. Cl. G11C 29/00; G11C 17/16; G11C 17/18

(52) U.S. Cl. CPC G11C 29/787; G11C 17/16; G11C 17/18

(57) ABSTRACT

The present application discloses an efuse memory, and an efuse unit includes: a main fuse, a backup fuse, a main selection control transistor, and a backup selection control transistor. A first end of the main fuse and a first end of the backup fuse are connected. The main selection control transistor is connected between a second end of the main fuse and a source port. The backup selection control transistor is connected between a second end of the backup fuse and the source port. The second end of the backup fuse serves as a read port. In a programming operation, the main fuse and the backup fuse form a parallel structure. In a read operation, the backup fuse and the main fuse form a series structure. The present application also discloses a method for operating an efuse memory.

### CROSS-REFERENCES TO RELATED APPLICATIONS

This application claims priority to Chinese patent application No. CN202411216062.6, filed on Aug. 30, 2024, the disclosure of which is incorporated herein by reference in its entirety.

### TECHNICAL FIELD

The present application relates to a semiconductor integrated circuit, in particular, to an electronic fuse (efuse) memory. The present application also relates to a method for operating the efuse memory.

### BACKGROUND

Efuse realizes on-chip programming functions by blowing a fuse, and has an important index, programming reliability. For effuse, programing failures may occur for various reasons in practice. However, efuse has a one-time programming operation since the resistance of the fuse, once it is changed, is not changed anymore, and thus, erroneous data can not be corrected by repeated programming. For an existing efuse memory, a fail-to-write-1 problem occurs under advanced processes when testing, i.e., programming of a certain bit fails, still with a read result of 0 after programming.

Generally, the resistance value of the fuse is 10 ohms to 20 ohms before programming.

After programming for the fuse, a normal resistance value is more than 100K ohms; however, a failure resistance value is about a few hundreds of ohms ˜2 k ohms; and the failure resistance value of a few hundreds of ohms ˜2 k ohms is still read as 0 in a read process, causing the fail-to-write-1 problem, thereby affecting reliability of an efuse memory.

For the efuse memory, its programming reliability is increased in an existing improvement method by a two-position redundant backup mode, that is, a same content is written to 2 efuse units when programming, and output is produced after logic values of the two units are subjected to or-logic in a read operation. As long as a programming failure does not occur for the two units at the same time, a correct value can be output. This method, however, has a disadvantage that an area increases by 100%.

Referring to FIG. 1A, it is a circuit diagram of an efuse unit of an existing efuse memory; and the efuse unit 101 comprises a fuse 102 and a selection control transistor N101 for which usually an NMOS transistor is employed. A first end of the fuse 102 serves as a port connecting a bit line BL to a sensitivity amplifier (SA), the SA in FIG. 1A indicating an input of a sensitivity amplifier.

A gate of the selection control transistor N101 is connected to a word line WL.

Referring to FIG. 1B, it is a circuit diagram of an efuse array of an existing efuse memory; and FIG. 1B shows an array formed by arranging m×n efuse units 101.

In the efuse array:

gates of selection control transistors N101 of efuse units 101 in the same row are connected to the same word line WL. In total, m rows of the word lines WL are shown in FIG. 1B, and the main word lines in the rows are labeled by WL1 to WLm, respectively.

First ends of fuses 102 of efuse units 101 in the same column are connected to the same bit line BL. In total, n columns of the bit lines BL are shown in FIG. 1B, and the bit lines BL in the columns are labeled by BL1, BL2 to BLn, respectively.

The bit lines BL are each connected to a supply voltage VDDQ by a power control transistor 103 whose gate is connected to a power control signal. The power control signals in the columns in FIG. 1B are labeled by BL1C, BL2C to BLnC, respectively. For the power control transistor 103, a PMOS transistor is employed. The power control transistors 103 in the columns in FIG. 1B are indicated by Mp.

The bit lines BL are each connected to a one-position sensitive amplifier by one read control transistor 104, the gate of which is connected to a read control signal RD. For the read control transistor 104, an NMOS transistor is employed. In FIG. 1B, it shows inputs which are connected to n sensitive amplifiers, and are indicated by to SA1, to SA2 to SAn, respectively.

Referring to FIG. 2, it is a unit circuit structure diagram of an existing efuse memory employing a two-position redundant backup; in FIG. 2, one memory unit in deed comprises two efuse units shown in FIG. 1A which are indicated by 101a and 101b, respectively. Under the control of an address control device 105, the two efuse units 101a and 101b may be wrote with the same content when programming.

In a read process, the values of the two efuse units 101a and 101b are read simultaneously under the control of the address control device 105, and then on the read values of the two efuse units 101a and 101b, an or operation is performed by employing an or gate 106, and the result of the or operation is output data Dout. It can be seen that, when it fails to write 1 to the efuse unit 101a, because it is successful to write 1 to the efuse unit 101b, the output data Dout remains 1; in contrast, when when it fails to write 1 to the efuse unit 101b, because it is successful to write 1 to the efuse unit 101a, the output data Dout remains 1. Therefore, only if neither of the efuse units 101a and 101b is subjected to a programming failure, correct data can be output finally to realize a two-position redundant backup. However, it can be seen from FIG. 2, the whole memory unit has two efuse units, doubling a unit area.

### BRIEF SUMMARY

According to some embodiments in this application, an efuse memory disclosed in this application comprising: an efuse unit.

The efuse unit comprises a main fuse, a backup fuse, a main selection control transistor, and a backup selection control transistor.

A first end of the main fuse and a first end of the backup fuse are connected and serve as a bit line port.

A gate of the main selection control transistor serves as a main word line port.

A gate of the backup selection control transistor serves as a backup word line port.

The main selection control transistor is connected between a second end of the main fuse and a source port.

The backup selection control transistor is connected between a second end of the backup fuse and the source port.

The second end of the backup fuse serves as a read port.

In a programming operation, the backup fuse and the main fuse form a parallel structure between the bit line port and the source port, the backup fuse and the main fuse being programmed independently.

In a read operation, the backup fuse and the main fuse form a series structure between the read port and the source port, the backup selection control transistor is disconnected, the main selection control transistor is conductive, and a read path comprises the series structure.

When the main fuse is subjected to a programming failure, the main fuse has a failure resistance, the backup fuse has a backup programming resistance, a resistance of the series structure is the sum of the failure resistance and the backup programming resistance; and the magnitude of the backup programming resistance ensures that the resistance of the series structure is greater than a first threshold value which is a resistance threshold value for logic determination of the efuse unit that is in a programmed state.

In some cases, the programming operation comprises a main programming operation in which the backup selection control transistor is disconnected and the main selection control transistor is conductive.

When the main fuse is subjected to normal programming, the main fuse has a main programming resistance after the main programming operation.

When the main fuse is subjected to a programming failure, the main fuse has a failure resistance after the main programming operation.

The main fuse has a first initial resistance before the main programming operation.

In some cases, the programming operation comprises a backup programming operation in which the backup selection control transistor is conductive and the main selection control transistor is disconnected.

The backup fuse has a backup programming resistance after the backup programming operation.

The backup fuse has a second initial resistance before the backup programming operation.

In some cases, in a read operation, when the main fuse is subjected to normal programming, the main fuse has the main programming resistance, the backup fuse has the second initial resistance, and a resistance of the series structure is the sum of the main programming resistance and the second initial resistance.

In some cases, the first initial resistance is less than tens of ohms, the main programming resistance is greater than 100 k ohms, and the failure resistance is a few hundreds of ohms ˜2 k ohms.

In some cases, the first threshold value is a few thousands of ohms.

The backup programming resistance is a few thousands of ohms.

The backup fuse is not flown after the backup programming operation.

The programming current for the backup programming operation is less than that for the main programming operation; and the backup selection control transistor has a size smaller than that of the main selection control transistor.

The backup selection control transistor is NMOS and the main selection control transistor is NMOS.

The source port is grounded.

In some cases, the efuse memory further comprise an efuse array formed by connecting a plurality of the efuse units.

In the efuse array:
the main word line ports of the efuse units in the same row are connected to the same main word line.

The backup word line ports of the efuse units in the same row are connected to the same backup word line.

The bit line ports of the efuse units in the same column are connected to the same bit line.

The read ports of the efuse units in the same column are connected to the same read line.

The bit lines are each connected to a power supply voltage by one power control transistor, the gate of the power control transistor being connected to a power supply control signal.

The read lines are each connected to a one-position sensitive amplifier by one read control transistor, the gate of the read control transistor being connected to a read control signal.

In some cases, when the main programming operation is performed on a selected efuse unit, the main word line of the selected efuse unit has a high level, the backup word line has a low level, the power control signal has a low level, and the read control signal has a low level.

When the backup programming operation is performed on the selected efuse unit, the main word line of the selected efuse unit has a low level, the backup word line has a high level, the power control signal has a low level, and the read control signal has a low level.

When a read operation is performed on the selected efuse unit, the main word line of the selected efuse unit has a high level, the backup word line has a low level, the power control signal has a high level, the read control signal has a high level, and the sensitive amplifiers at respective positions operate.

The present application provides a method for operating an efuse memory, wherein the efuse memory comprises an efuse unit.

The efuse unit comprises a main fuse, a backup fuse, a main selection control transistor, and a backup selection control transistor.

A first end of the main fuse and a first end of the backup fuse are connected and serve as a bit line port.

A gate of the main selection control transistor serves as a main word line port.

A gate of the backup selection control transistor serves as a backup word line port.

The main selection control transistor is connected between a second end of the main fuse and a source port.

The backup selection control transistor is connected between a second end of the backup fuse and the source port.

The second end of the backup fuse serves as a read port.

The operation method comprises a programming operation and a read operation.

In a programming operation, the backup fuse and the main fuse form a parallel structure between the bit line port and the source port, the backup fuse and the main fuse being programmed independently.

In a read operation, the backup fuse and the main fuse form a series structure between the read port and the source port, the backup selection control transistor is disconnected, the main selection control transistor is conductive, and a read path comprises the series structure.

When the main fuse is subjected to a programming failure, the main fuse has a failure resistance, the backup fuse is subjected to the programming operation and has a backup programming resistance, a resistance of the series structure is the sum of the failure resistance and the backup programming resistance; and the magnitude of the backup programming resistance ensures that the resistance of the series structure is greater than a first threshold value which is a resistance threshold value for logic determination of the efuse unit that is in a programmed state.

In some cases, the programming operation comprises a main programming operation in which the backup selection control transistor is disconnected, the main selection control transistor is conductive, and a programming current between the bit line port and the source port flows through the main fuse to realize programming of the main fuse.

When the main fuse is subjected to normal programming, the main fuse has a main programming resistance after the main programming operation.

When the main fuse is subjected to a programming failure, the main fuse has a failure resistance after the main programming operation.

The main fuse has a first initial resistance before the main programming operation.

In some cases, when the main fuse is subjected to a programming failure, the programming operation further comprises performing a backup programming operation in which the backup selection control transistor is conductive, the main selection control transistor is disconnected, and a programming current between the bit line port and the source port flows through the backup fuse to achieve programming of the backup fuse.

The backup fuse has a backup programming resistance after the backup programming operation.

The backup fuse has a second initial resistance before the backup programming operation.

In some cases, the programming operation does not perform the backup programming operation when the main fuse is subjected to normal programming.

In a read operation, when the main fuse is subjected to normal programming, the main fuse has the main programming resistance, the backup fuse has the second initial resistance, and a resistance of the series structure is the sum of the main programming resistance and the second initial resistance.

In some cases, the first initial resistance is less than tens of ohms, the main programming resistance is greater than 100 k ohms, and the failure resistance is a few hundreds of ohms ˜2 k ohms.

In some cases, the first threshold value is a few thousands of ohms.

The backup programming resistance is a few thousands of ohms.

The backup fuse is not flown after the backup programming operation.

The programming current for the backup programming operation is less than that for the main programming operation; and the backup selection control transistor has a size smaller than that of the main selection control transistor.

In some cases, the backup selection control transistor is NMOS and the main selection control transistor is NMOS; and
the source port is grounded.

In some cases, the efuse memory further comprise an efuse array formed by connecting a plurality of the efuse units.

In the efuse array:
the main word line ports of the efuse units in the same row are connected to the same main word line.

The backup word line ports of the efuse units in the same row are connected to the same backup word line.

The bit line ports of the efuse units in the same column are connected to the same bit line.

The read ports of the efuse units in the same column are connected to the same read line.

The bit lines are each connected to a power supply voltage by one power control transistor, the gate of the power control transistor being connected to a power supply control signal.

The read lines are each connected to a one-position sensitive amplifier by one read control transistor, the gate of the read control transistor being connected to a read control signal.

In some cases, when the main programming operation is performed on a selected efuse unit, the main word line of the selected efuse unit is applied with a high level, the backup word line is applied with a low level, the power supply control signal is applied with a low level, and the read control signal is applied with a low level.

When the backup programming operation is performed on the selected efuse unit, the main word line of the selected efuse unit is applied with a low level, the backup word line is applied with a high level, the power control signal is applied with a low level, and the read control signal is applied with a low level.

When a read operation is performed on the selected efuse unit, the main word line of the selected efuse unit is applied with a high level, the backup word line is applied with a low level, the power control signal is applied with a high level, the read control signal is applied with a high level, and the sensitive amplifiers at respective positions operate.

In the efuse unit of the present application, the backup fuse and backup selection control transistor are provided in addition to the main fuse and the main selection control transistor, the read port is provided at the second end of the backup fuse, and the first end of the main fuse and the first end of the backup fuse are connected to the bit line port; wherein the main fuse and the main selection control transistor, and the backup fuse and the backup selection control transistor are respectively provided in parallel, so that the backup fuse and main fuse when a programming operation are in a parallel structure, thereby achieving independent programming of the backup fuse and main fuse; whereas, the provision of the read port enables in-series connection of the backup fuse and main fuse during a read operation, so that the backup fuse can be programmed additionally when the main fuse is subjected to a programming failure, enabling the resistance of the series structure that is still greater than the first threshold value, and in this way, the efuse unit still maintains an effective programming state. That is, even if the main fuse is subjected to a programming failure occurs, the entire efuse unit remains effectively programmed due to additional programming of the backup fuse. So, the present application can solve the programming failure problem for the efuse unit, increasing its programming reliability.

In addition, in the present application, the magnitude of the backup programming resistance of the backup fuse is required only to ensure that the resistance of the series structure is greater than the first threshold value, it usually is only a few thousands of ohms, such as 5 k ohms, the failure resistance of the main fuse itself is a few hundreds of ohms ˜2 k ohms, the backup programming resistance needs to be greater than the first threshold value minus the failure resistance, so the backup programming resistance is only a few thousands of ohms compared with the magnitude of the main programming resistance that is greater than 100 ohms, in this way, a programming requirement for the backup fuse is greatly reduced, and when programming, there is no need that the backup fuse is blown, with the only need to slightly increase the value resistance of the backup fuse by electromigration, and thus, a programming current required is relatively small, in this way, the size of the backup fuse itself can be set smaller than the main fuse, and meanwhile, the size of the backup selection control transistor is also much smaller than that of the main selection control transistor, so the additional backup fuse and backup selection control transistor require a small area, with little effect on an area of an entire efuse unit.

In addition, the present application can realize programming of the backup fuse only when the main fuse is subjected to a programming failure, so the efuse unit of the present application is not adversely affected in terms of normal programming, and programming efficiency is not affected.

Therefore, compared with the existing two-position redundant backup structure, the efuse unit of the present application not only has a much smaller increase in area, but also completely avoids the programming failure problem.

### BRIEF DESCRIPTION OF THE DRAWINGS

The present application is described in further detail below in conjunction with figures and detailed description:

FIG. 1A is a circuit diagram of an efuse unit of an existing efuse memory;

FIG. 1B is a circuit diagram of an efuse array of an existing efuse memory;

FIG. 2 is a unit circuit structure diagram of an existing efuse memory employing a two-position redundant backup;

FIG. 3 is a circuit diagram of an efuse unit of an efuse memory of an embodiment of the present application;

FIG. 4 is a circuit diagram of an efuse array of an efuse memory of an embodiment of the present application;

FIG. 5 is a circuit diagram when an efuse memory of an embodiment of the present application performs a main programming operation on a selected efuse unit;

FIG. 6 is a circuit diagram when an efuse memory performs a backup programming operation on a selected efuse unit in an embodiment of the present application;

FIG. 7 is a circuit diagram when an efuse memory of an embodiment of the present application performs a read operation on a selected efuse unit.

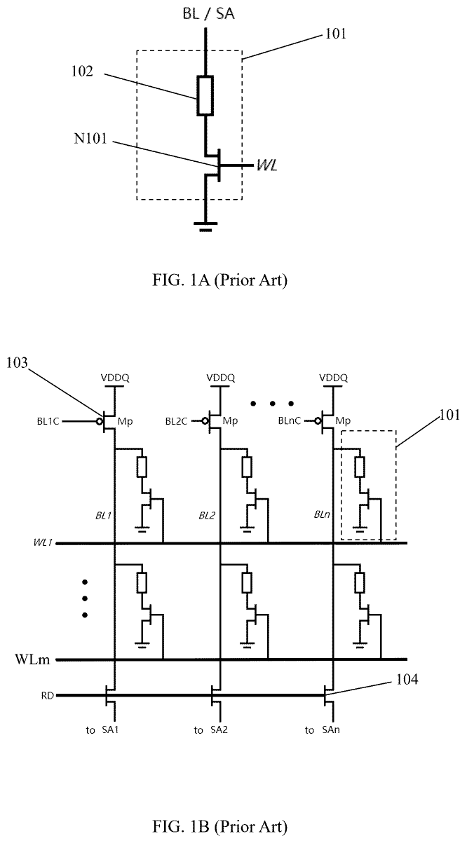

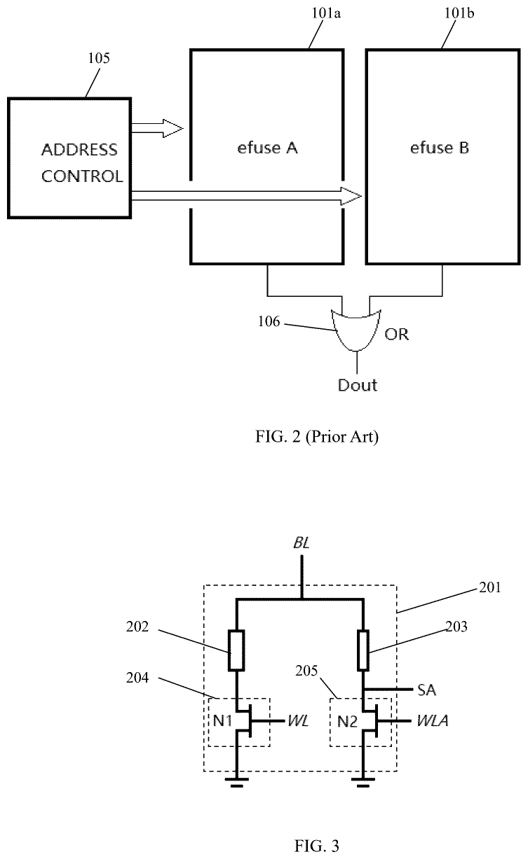

### DETAILED DESCRIPTION OF THE DISCLOSURE

Referring to FIG. 3, it is a circuit diagram of an efuse unit 201 of an efuse memory of an embodiment of the present application, the efuse memory comprising an efuse unit 201.

The efuse unit 201 comprises: a main fuse 202, a backup fuse 203, a main selection control transistor 204, and a backup selection control transistor 205.

A first end of the main fuse 202 and a first end of the backup fuse 203 are connected and serve as a bit line port, and the bit line port is used to connect with a bit line BL.

A gate of the main selection control transistor 204 serves as a main word line port. The main word line port is used to connect with the main word line WL.

A gate of the backup selection control transistor 205 serves as a backup word line port. The backup word line port is used to connect with the backup word line WLA.

The main selection control transistor 204 is connected between a second end of the main fuse 202 and the source port.

The backup selection control transistor 205 is connected between a second end of the backup fuse 203 and the source port. In an embodiment of the present application, the backup selection control transistor 205 is NMOS and the main selection control transistor 204 is NMOS. The source port is grounded. In FIG. 3, the main selection control transistor 204 is further indicated by N1 and the backup selection control transistor 205 is further indicated by N2.

The second end of the backup fuse 203 serves as a read port. The read port is used for connection with a sensitive amplifier, SA shown in FIG. 3 indicating an input of an sensitive amplifier.

In the programming operation, the backup fuse 203 and the main fuse 202 form a parallel structure between the bit line port and the source port, and the backup fuse 203 and the main fuse 202 are programmed independently.

Referring to FIG. 3, in a programming operation, the sensitive amplifier is not activated, thus the bit line port is not connected to the sensitive amplifier, the backup fuse 203 and the main fuse 202 form a parallel structure between the bit line port and the source port, and since the main selection control transistor 204 and the backup selection control transistor 205 can be independently controlled via the main word line WL and the backup word line WLA, respectively, the backup fuse 203 and the main fuse 202 can each achieve independent programming.

In a read operation, the backup fuse 203 and the main fuse 202 form a series structure between the read port and the source port, the backup selection control transistor 205 is disconnected, the main selection control transistor 204 is conductive, and a read path comprises the series structure.

Referring to FIG. 3, during a read operation, a signal of the bit line BL is turned off and the backup selection control transistor 205 is disconnected, but the read port is connected to the sensitive amplifier, thus, the backup fuse 203 and the main fuse 202 form a series structure, and a read resistance is no longer the resistance of the main fuse 202 only, but the sum of the resistance of the backup fuse 203 and the resistance of the main fuse 202.

When the main fuse 202 is subjected to a programming failure, the main fuse 202 has a failure resistance, the backup fuse 203 has a backup programming resistance, and the resistance of the series structure is the sum of the failure resistance and the backup programming resistance; and the magnitude of the backup programming resistance ensures that the resistance of the series structure is greater than a first threshold value which is a resistance threshold value for logic determination of the efuse unit 201 that is in a programming state.

Referring to FIG. 3, in an embodiment of the present application, the backup fuse 203 has the backup programming resistance by setting, so that even though the main fuse 202 has a failure resistance, the resistance sum of the backup fuse and main fuse still is greater than the first threshold value, and thus the programming state of the entire efuse unit 201 is still an effective programming state, thereby solving the defect of the main fuse 202 being a failed programming state.

In an embodiment of the present application, the programming operation comprises a main programming operation in which the backup selection control transistor 205 is disconnected and the main selection control transistor 204 is conductive. Referring to FIG. 3, since the main selection control transistor 204 is conductive, a programming current flows through the main fuse 202 to realize programming of the main fuse 202. Meanwhile, since the backup selector tube 205 is disconnected, the programming current does not flow through the backup fuse 203.

When the main fuse 202 is subjected to normal programming, the main fuse 202 has a main programming resistance after the main programming operation. Generally, when normal programming, the main fuse 202 is blown, so that the resistance of the main fuse 202 increases, i.e. the main programming resistance has a relatively large value.

When the main fuse 202 is subjected to a programming failure, the main fuse 202 has a failure resistance after the main programming operation. Generally, when a programming failure, the main fuse 202 is not blown, so that the main fuse 202 has a resistance still having a relatively small value and less than the first threshold value.

The main fuse 202 has a first initial resistance before the main programming operation.

In an embodiment of the present application, the programming operation comprises a backup programming operation in which the backup selection control transistor 205 is conductive and the main selection control transistor 204 is disconnected.

The backup fuse 203 has a backup programming resistance after the backup programming operation.

The backup fuse 203 has a second initial resistance before the backup programming operation.

In an embodiment of the present application, in a read operation, when the main fuse 202 is subjected to normal programming, the main fuse 202 has the main programming resistance, the backup fuse 203 has the second initial resistance, and a resistance of the series structure is the sum of the main programming resistance and the second initial resistance.

That is, in an embodiment of the present application, the backup programming operation only needs to be performed on the efuse unit in which the main fuse 202 is subjected to a programming failure, reducing a total number of programming times. Of course, in other embodiments, the backup programming operation may be performed on the efuse unit in which the main fuse 202 is subjected to effective programming, and in such a case, the programming result for the whole efuse unit remains effective.

In some embodiments, the first initial resistance is less than tens of ohms, for example, 10 ohms ˜20 ohms; the main programming resistance is greater than 100 k ohms; and the failure resistance is a few hundreds of ohms ˜2 k ohms, for example 1 k ohms ˜2 k ohms.

The first threshold is a few thousands of ohms, for example, 5k ohms.

The backup programming resistance is a few thousands of ohms. Generally, a minimum required value of the backup programming resistance is obtained by subtracting a minimum value of the failure resistance from the first threshold value, and it is sufficient to set the backup programming resistance according to a minimum required value greater than the backup programming resistance.

In an embodiment of the present application, the backup fuse 203 is not flown after the backup programming operation. Since the backup programming operation does not require that the backup fuse 203 is blown, a programming current required for the backup programming operation is relatively small. Thus, the programming current for the backup programming operation is smaller than that for the main programming operation; and the backup selection control transistor 205 has a size smaller than that of the main selection control transistor 204, and also, the backup fuse 203 itself has a size that can be smaller than that of the main fuse 202, so that the area increase brought about by the backup fuse 203 and the backup selection control transistor 205 can be reduced, with a greatly reduced area relative to an unit structure of an existing efuse memory employing a two-position redundant backup. As known to those skilled in the art, for an MOS transistor, when the current flowing through it is reduced, a size of a device can be reduced, e.g., a smaller channel width indicates a smaller source leakage current of a device when a channel length is unchanged.

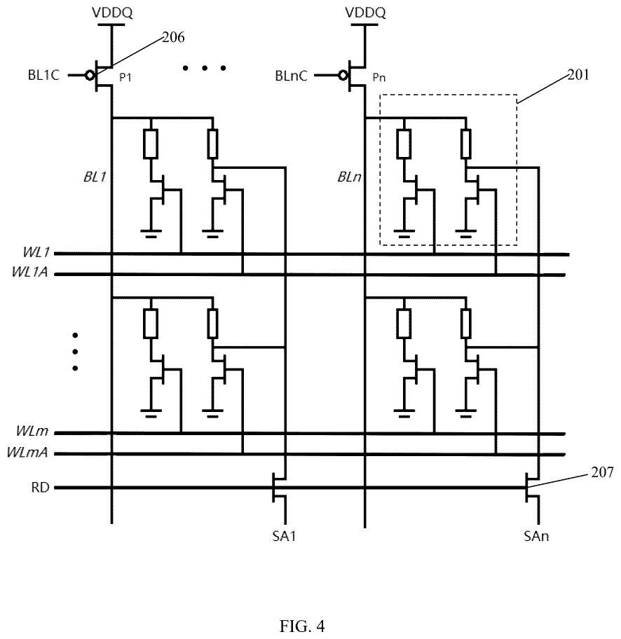

Referring to FIG. 4, it is a circuit diagram of an efuse array of an efuse memory of an embodiment of the present application; and the efuse memory further comprises an efuse array formed by connecting a plurality of the efuse units 201, and FIG. 4 shows an m×n array, i.e., an array having m rows and n columns, n and m being both integers greater than or equal to 2 in FIG. 4.

### In the Efuse Array:

the main word line ports of the efuse units 201 in the same row are connected to the same main word line. In total, m rows of the main word lines WL are shown in FIG. 4, and the main word lines in the rows are labeled by WL1 to WLm, respectively.

The backup word line ports of the efuse units 201 in the same row are connected to the same backup word line WLA. In total, m rows of the backup word lines WLA are shown in FIG. 4, and the backup word lines WLA in the rows are labeled by WL1A to WLmA, respectively.

The bit line ports of the efuse units 201 in the same column are connected to the same bit line BL. In total, n columns of the bit lines BL are shown in FIG. 4, and the bit lines BL in the columns are labeled by BL1 to BLn, respectively.

The read ports of the efuse units 201 in the same column are connected to the same read line.

The bit lines BL are each connected to a supply voltage VDDQ by one power control transistor 206, and the gate of the power control transistor 206 is connected to a power supply control signal. The power control signals in the rows in FIG. 4 are labeled by BL1C to BLnC, respectively. In an embodiment of the present application, the power control transistor 206 is a PMOS transistor. In FIG. 4, the power control transistors 206 in the rows are labeled by P1 to Pn, respectively.

The read lines are each connected to a one-position sensitive amplifier by one read control transistor 207, and the gate of the read control transistor 207 is connected to a read control signal RD. In an embodiment of the present application, the read control transistor 207 is an NMOS transistor. In FIG. 4, the inputs of n sensitive amplifiers are shown, indicated by SA1 to SAn, respectively.

In an embodiment of the present application, when the main programming operation is performed on a selected efuse unit 201, the main word line WL of the selected efuse unit 201 has a high level, the backup word line WLA has a low level, the power control signal has a low level, and the read control signal RD has a low level.

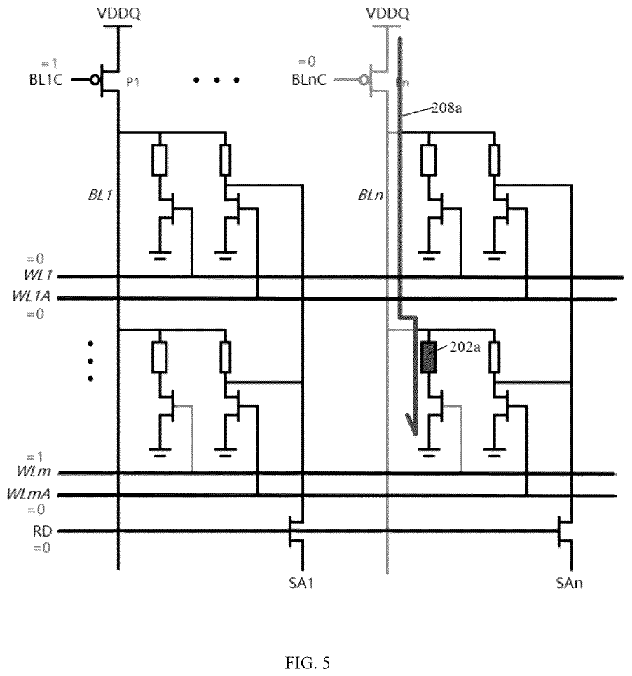

Referring to FIG. 5, it is a circuit diagram when an efuse memory of an embodiment of the present application performs a main programming operation on a selected efuse unit; and in FIG. 5, the efuse unit in the mth row and nth column is the selected efuse unit 201, the arrowed line corresponding to a label 208a indicates a flow path of a programming current, and the programming current passes through the main fuse indicated by using a label 202a alone to finally achieve programming of the main fuse 202a.

When the main fuse 202a is subjected to a programming failure, the backup programming operation needs to be performed on the selected efuse unit 201.

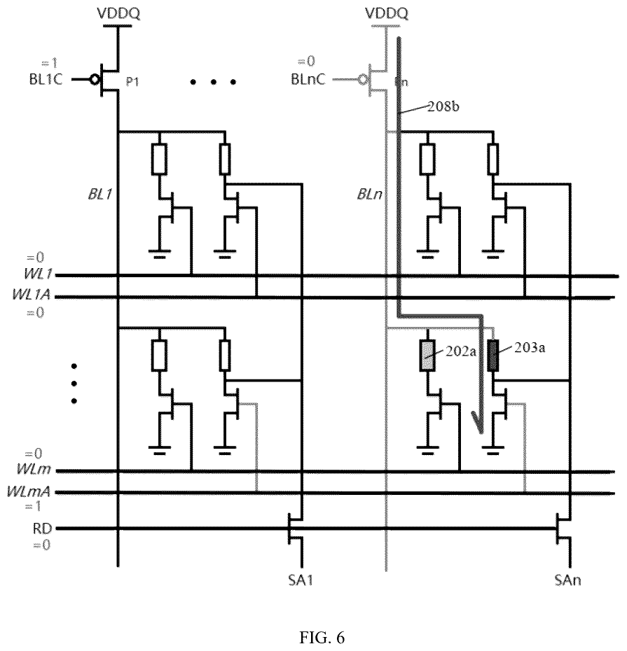

When the backup programming operation is performed on selected efuse unit 201, the main word line WL of the selected efuse unit 201 has a low level, the backup word line WLA has a high level, the power control signal has a low level, and the read control signal RD has a low level. Referring to FIG. 6, it is a circuit diagram when an efuse memory performs a backup programming operation on a selected efuse unit in an embodiment of the present application; and in FIG. 6, the arrowed line corresponding to a label 208b indicates a flow path of a programming current, and the programming current passes through the backup fuse indicated by employing a label 203a alone to finally realize programming of the backup fuse 203a.

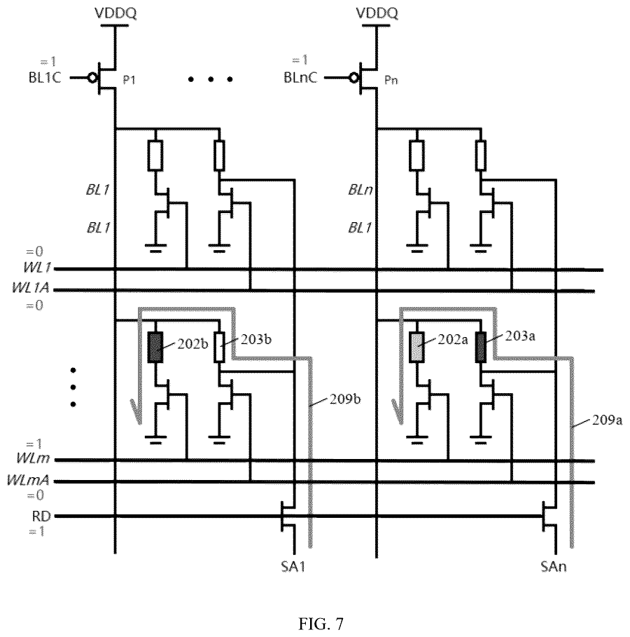

When a read operation is performed on the selected efuse unit 201, the main word line WL of the selected efuse unit 201 has a high level, the backup word line WLA has a low level, the power control signal has a high level, the read control signal RD has a high level, and the sensitive amplifiers at respective positions operate. Referring to FIG. 7, it is a circuit diagram when an efuse memory of an embodiment of the present application performes a read operation on a selected efuse unit. In FIG. 7, parallel reading of data of n-position efuse units 201 in the same row can be realized, and a red row shown in FIG. 7 is the mth row, where an input SA1 of the 1st-position sensitive amplifier in the 1st column reads a signal corresponding to a series structure of a main fuse labeled by a label 202b alone and a backup fuse labeled by a label 203b alone, and it is assumed that the main fuse 202b is subjected to normal programming, the backup fuse 203b needs to be not programmed anymore and has the second initial resistance; and an input SAn of the nth-position sensitive amplifier in the nth column reads the signal corresponding to the series structure of the main fuse 202a and the backup fuse 203a, and it is assumed that the main fuse 202a is subjected to a programming failure, the backup fuse 203b needs to be programmed and has the backup programming resistance.

In the efuse unit 201 of the embodiment of the present application, the backup fuse 203 and backup selection control transistor 205 are provided in addition to the main fuse 202 and the main selection control transistor 204, the read port is provided at the second end of the backup fuse 203, and the first end of the main fuse 202 and the first end of the backup fuse 203 are connected to the bit line port; wherein the main fuse 202 and the main selection control transistor 204, and the backup fuse 203 and the backup selection control transistor 205 are respectively provided in parallel, so that the backup fuse 203 and main fuse 202 are in a parallel structure when a programming operation, thereby achieving independent programming of the backup fuse 203 and main fuse 202; whereas, the provision of the read port enables in-series connection of the backup fuse 203 and main fuse 202 during a read operation, so that the backup fuse 203 can be programmed additionally when the main fuse 202 is subjected to a programming failure, enabling the resistance of the series structure that is still greater than the first threshold value, and in this way, the efuse unit 201 still maintains an effective programming state. That is, even if the main fuse is subjected to a programming failure 202 occurs, the entire efuse unit 201 remains effectively programmed due to additional programming of the backup fuse 203. So, the present application can solve the programming failure problem for the efuse unit 201, increasing its programming reliability.

In addition, in the embodiment of the present application, the magnitude of the backup programming resistance of the backup fuse 203 is required only to ensure that the resistance of the series structure is greater than the first threshold value, it usually is only a few thousands of ohms, such as 5 k ohms, the failure resistance of the main fuse 202 itself is a few hundreds of ohms ˜2 k ohms, the backup programming resistance needs to be greater than the first threshold value minus the failure resistance, so the backup programming resistance is only a few thousands of ohms compared with the magnitude of the main programming resistance that is greater than 100 ohms, in this way, a programming requirement for the backup fuse 203 is greatly reduced, and when programming, there is no need that the backup fuse 203 is blown, with the only need to slightly increase the value resistance of the backup fuse 203 by electromigration, and thus, a programming current required is relatively small, in this way, the size of the backup fuse 203 itself can be set smaller than the main fuse 202, and meanwhile, the size of the backup selection control transistor 205 is also much smaller than that of the main selection control transistor 204, so the additional backup fuse 203 and backup selection control transistor 205 require a small area, with little effect on an area of an entire efuse unit 201.

In addition, the embodiment of the present application can realize programming of the backup fuse 203 only when the main fuse 202 is subjected to a programming failure, so the efuse unit 201 of the embodiment of the present application is not adversely affected in terms of normal programming, and programming efficiency is not affected.

Therefore, compared with the existing two-position redundant backup structure, the efuse unit 201 of the embodiment of the present application not only has a much smaller increase in area, but also completely avoids the programming failure problem.

In a method for operating an efuse memory in an embodiment of the present application, the efuse memory comprises an efuse unit 201. Referring to FIG. 3, the efuse unit 201 comprises: a main fuse 202, a backup fuse 203, a main selection control transistor 204, and a backup selection control transistor 205.

A first end of the main fuse 202 and a first end of the backup fuse 203 are connected and serve as a bit line port, and the bit line port is used to connect with a bit line BL.

A gate of the main selection control transistor 204 serves as a main word line port. The main word line port is used to connect with the main word line WL.

A gate of the backup selection control transistor 205 serves as a backup word line port. The backup word line port is used to connect with the backup word line WLA.

The main selection control transistor 204 is connected between a second end of the main fuse 202 and the source port.

The backup selection control transistor 205 is connected between a second end of the backup fuse 203 and the source port. In an embodiment of the present application, the backup selection control transistor 205 is NMOS and the main selection control transistor 204 is NMOS. The source port is grounded. In FIG. 3, the main selection control transistor 204 is further indicated by N1 and the backup selection control transistor 205 is further indicated by N2.

The second end of the backup fuse 203 serves as a read port. The read port is used to connect with a sensitive amplifier (SA), and SA shown in FIG. 3 indicates an input of the sensitive amplifier.

The operation method comprises a programming operation and a read operation.

In the programming operation, the backup fuse 203 and the main fuse 202 form a parallel structure between the bit line port and the source port, and the backup fuse 203 and the main fuse 202 are programmed independently.

Referring to FIG. 3, in the programming operation, the sensitive amplifier is not activated, thus the bit line port is not connected to the sensitive amplifier, the backup fuse 203 and the main fuse 202 form a parallel structure between the bit line port and the source port, and since the main selection control transistor 204 and the backup selection control transistor 205 can be independently controlled via the main word line WL and the backup word line WLA, respectively, the backup fuse 203 and the main fuse 202 can each achieve independent programming.

In the read operation, the backup fuse 203 and the main fuse 202 form a series structure between the read port and the source port, the backup selection control transistor 205 is disconnected, the main selection control transistor 204 is conductive, and a read path comprises the series structure.

Referring to FIG. 3, during a read operation, a signal of the bit line BL is turned off and the backup selection control transistor 205 is disconnected, but the read port is connected to the sensitive amplifier, thus, the backup fuse 203 and the main fuse 202 form a series structure, and a read resistance is no longer the resistance of the main fuse 202 only, but the sum of the resistance of the backup fuse 203 and the resistance of the main fuse 202.

When the main fuse 202 is subjected to a programming failure, the main fuse 202 has a failure resistance, the backup fuse 203 has a backup programming resistance, and the resistance of the series structure is the sum of the failure resistance and the backup programming resistance; and the magnitude of the backup programming resistance ensures that the resistance of the series structure is greater than a first threshold value which is a resistance threshold value for logic determination of the efuse unit 201 that is in a programming state.

Referring to FIG. 3, in an embodiment of the present application, the backup fuse 203 has the backup programming resistance by setting, so that even though the main fuse 202 has a failure resistance, the resistance sum of the backup fuse and main fuse still is greater than the first threshold value, and thus the programming state of the entire efuse unit 201 is still an effective programming state, thereby solving the defect of the main fuse 202 being a failed programming state.

In an embodiment of the present application, the programming operation comprises a main programming operation in which the backup selection control transistor 205 is disconnected and the main selection control transistor 204 is conductive. Referring to FIG. 3, since the main selection control transistor 204 is conductive, a programming current flows through the main fuse 202 to realize programming of the main fuse 202. Meanwhile, since the backup selector tube 205 is disconnected, the programming current does not flow through the backup fuse 203.

When the main fuse 202 is subjected to normal programming, the main fuse 202 has a main programming resistance after the main programming operation. Generally, when normal programming, the main fuse 202 is blown, so that the resistance of the main fuse 202 increases, i.e. the main programming resistance has a relatively large value.

When the main fuse 202 is subjected to a programming failure, the main fuse 202 has a failure resistance after the main programming operation. Generally, when a programming failure, the main fuse 202 is not blown, so that the main fuse 202 has a resistance still having a relatively small value and less than the first threshold value.

The main fuse 202 has a first initial resistance before the main programming operation.

In an embodiment of the present application, the programming operation comprises a backup programming operation in which the backup selection control transistor 205 is conductive and the main selection control transistor 204 is disconnected.

The backup fuse 203 has a backup programming resistance after the backup programming operation.

The backup fuse 203 has a second initial resistance before the backup programming operation.

In an embodiment of the present application, in a read operation, when the main fuse 202 is subjected to normal programming, the main fuse 202 has the main programming resistance, the backup fuse 203 has the second initial resistance, and a resistance of the series structure is the sum of the main programming resistance and the second initial resistance.

That is, in an embodiment of the present application, the backup programming operation only needs to be performed on the efuse unit in which the main fuse 202 is subjected to a programming failure, reducing a total number of programming times. Of course, in other embodiments, the backup programming operation may be performed on the efuse unit in which the main fuse 202 is subjected to effective programming, and in such a case, the programming result for the whole efuse unit remains effective.

In some embodiments, the first initial resistance is less than tens of ohms, for example, 10 ohms ˜20 ohms; the main programming resistance is greater than 100 k ohms; and the failure resistance is a few hundreds of ohms ˜2 k ohms, for example 1 k ohms ˜2 k ohms.

The first threshold is a few thousands of ohms, for example, 5 k ohms.

The backup programming resistance is a few thousands of ohms. Generally, a minimum required value of the backup programming resistance is obtained by subtracting a minimum value of the failure resistance from the first threshold value, and it is sufficient to set the backup programming resistance according to a minimum required value greater than the backup programming resistance.

In an embodiment of the present application, the backup fuse 203 is not flown after the backup programming operation. Since the backup programming operation does not require that the backup fuse 203 is blown, a programming current required for the backup programming operation is relatively small. Thus, the programming current for the backup programming operation is smaller than that for the main programming operation; and the backup selection control transistor 205 has a size smaller than that of the main selection control transistor 204, and also, the backup fuse 203 itself has a size that can be smaller than that of the main fuse 202, so that the area increase brought about by the backup fuse 203 and the backup selection control transistor 205 can be reduced, with a greatly reduced area relative to an unit structure of an existing efuse memory employing a two-position redundant backup. As known to those skilled in the art, for an MOS transistor, when the current flowing through it is reduced, a size of a device can be reduced, e.g., a smaller channel width indicates a smaller source leakage current of a device when a channel length is unchanged.

Referring to FIG. 4, it is a circuit diagram of an efuse array of an efuse memory of an embodiment of the present application; and the efuse memory further comprises an efuse array formed by connecting a plurality of the efuse units 201, and FIG. 4 shows an m×n array, i.e., an array having m rows and n columns, n and m being both integers greater than or equal to 2 in FIG. 4.

### In the Efuse Array:

the main word line ports of the efuse units 201 in the same row are connected to the same main word line. In total, m rows of the main word lines WL are shown in FIG. 4, and the main word lines in the rows are labeled by WL1 to WLm, respectively.

The backup word line ports of the efuse units 201 in the same row are connected to the same backup word line WLA. In total, m rows of the backup word lines WLA are shown in FIG. 4, and the backup word lines WLA in the rows are labeled by WL1A to WLmA, respectively.

The bit line ports of the efuse units 201 in the same column are connected to the same bit line BL. In total, n columns of the bit lines BL are shown in FIG. 4, and the bit lines BL in the columns are labeled by BL1 to BLn, respectively.

The read ports of the efuse units 201 in the same column are connected to the same read line.

The bit lines BL are each connected to a supply voltage VDDQ by one power control transistor 206, and the gate of the power control transistor 206 is connected to a power supply control signal. The power control signals in the rows in FIG. 4 are labeled by BL1C to BLnC, respectively. In an embodiment of the present application, the power control transistor 206 is a PMOS transistor. In FIG. 4, the power control transistors 206 in the rows are labeled by P1 to Pn, respectively.

The read lines are each connected to a one-position sensitive amplifier by one read control transistor 207, and the gate of the read control transistor 207 is connected to a read control signal RD. In an embodiment of the present application, the read control transistor 207 is an NMOS transistor. In FIG. 4, the inputs of n sensitive amplifiers are shown, indicated by SA1 to SAn, respectively.

In an embodiment of the present application, when the main programming operation is performed on a selected efuse unit 201, the main word line WL of the selected efuse unit 201 is applied with a high level, the backup word line WLA is applied with a low level, the power control signal is applied with a low level, and the read control signal RD is applied with a low level.

Referring to FIG. 5, it is a circuit diagram when an efuse memory of an embodiment of the present application performs a main programming operation on a selected efuse unit; and in FIG. 5, the efuse unit in the mth row and nth column is the selected efuse unit 201, the arrowed line corresponding to a label 208a indicates a flow path of a programming current, and the programming current passes through the main fuse indicated by using a label 202a alone to finally achieve programming of the main fuse 202a. Main fuses of other unselected efuse units 201 have no current passed therethrough and have resistance values kept unchanged.

When the main fuse 202a is subjected to a programming failure, the backup programming operation needs to be performed on the selected efuse unit 201. When the backup programming operation is performed on selected efuse unit 201, the main word line WL of the selected efuse unit 201 is applied with a low level, the backup word line WLA is applied with a high level, the power control signal is applied with a low level, and the read control signal RD is applied with a low level. Referring to FIG. 6, it is a circuit diagram when an efuse memory performs a backup programming operation on a selected efuse unit in an embodiment of the present application; and in FIG. 6, the arrowed line corresponding to a label 208b indicates a flow path of a programming current, and the programming current passes through the backup fuse indicated by employing a label 203a alone to finally realize programming of the backup fuse 203a. Backup fuses of other unselected efuse units 201 have no current passed therethrough and have resistance values kept unchanged.

When a read operation is performed on the selected efuse unit 201, the main word line WL of the selected efuse unit 201 is applied with a high level, the backup word line WLA is applied with a low level, the power control signal is applied with a high level, the read control signal RD is applied with a high level, and the sensitive amplifiers at respective positions operate. Referring to FIG. 7, it is a circuit diagram when an efuse memory of an embodiment of the present application performes a read operation on a selected efuse unit. In FIG. 7, parallel reading of data of n-position efuse units 201 in the same row can be realized, and a red row shown in FIG. 7 is the mth row, where an input SA1 of the 1st-position sensitive amplifier in the 1st column reads a signal corresponding to a series structure of a main fuse labeled by a label 202b alone and a backup fuse labeled by a label 203b alone, and it is assumed that the main fuse 202b is subjected to normal programming, the backup fuse 203b needs to be not programmed anymore and has the second initial resistance; and an input SAn of the nth-position sensitive amplifier in the nth column reads the signal corresponding to the series structure of the main fuse 202a and the backup fuse 203a, and it is assumed that the main fuse 202a is subjected to a programming failure, the backup fuse 203b needs to be programmed and has the backup programming resistance. Therefore, as can be seen from FIG. 7, in the read mode, a read current of an input SA1 of the 1st-position sensitive amplifier flows through the main fuse and the backup fuse that are subjected to norm programming, and a resistance value after programming can be red to obtain a correct programmed value; and a read current of an input San of the nth-position sensitive amplifier in the nth column flows through the main fuse that is subjected to a programming failure and the backup fuse that is subjected to correct programming, and since the sum of the two resistance values is greater than the discriminating threshold of the sensitive amplifier, i.e., the first threshold, the sensitive amplifier can also output a correct logic value, thereby ensuring that the programming reliability of the entire efuse memory is not affected by a certain failed main fuse.

The embodiment of the present application, aiming to increase the programming reliability of the efuse unit, have additional one backup fuse and its control transistor on the basis of a conventional efuse fuse, realizing supplementary programming of the unit fuse having a programming failure, and separates the SA and the BL to form independent ports by modifying the position of the SA port, i.e., the read port, of the efuse unit, so as to obtain a final resistance value of a failed fuse after supplementary programming.

The embodiment of the present application, by improving the efuse unit and its array, can achieve a corrective operation performed on a unit having a programming failure, avoiding an occurred programming failure and thereby increase programming reliability. Mainly, one backup eFuse, i.e., a backup fuse 203, is added in a circuit of an existing efuse unit. These two eFuses are in an in-parallel connection manner in a programming mode, and can be programmed separately; and in a read mode, the resistances of the two fuses are in an in-series connection mode, and a read-out resistance value is the sum of two resistance values. Under a normal programming operation, programming is performed only on a conventional fuse. Only when there is a readout error after a failed programming, i.e., when a resistance value of a fuse does not reach the discrimination threshold, i.e., the first threshold value, the backup efuse of the fuse is enabled and is programmed. Although a resistance value of a failed fuse is relatively small, the resistance of the backup fuse after programming can make a remedy for the smaller resistance value of the former, i.e., the sum of the resistance values of the failed fuse and backup fuse can reach the discrimination threshold, avoiding that the programming failure problem occurs.

The embodiment of the present application adds one backup fuse on the basis of an existing efuse unit. Since the backup fuse with only a backup effect is in series connection with a conventional fuse, i.e., the main fuse 202, during a read operation, the resistance value of the backup fuse after programming does not need to be too large, so the programming current for the backup fuse is relatively small, with a control transistor size and a layout area that are also relatively small. In this way, in general, the efuse unit of the embodiment of the present application has a reduced area as compared with the storage unit of the existing efuse memory with a two-position redundant backup, and can completely avoid the programming failure problem.

The present application is described in detail above by specific embodiments which do not constitute a limitation on the present application. Without departing from the principle of the present application, those skilled in the art may also make many changes and improvements which should also be regarded as the scope of protection of the present application.

What is claimed is:

1. An efuse memory, wherein the effuse memory comprises an efuse unit;
the efuse unit comprises a main fuse, a backup fuse, a main selection control transistor, and a backup selection control transistor;
a first end of the main fuse and a first end of the backup fuse are connected and serve as a bit line port;
a gate of the main selection control transistor serves as a main word line port;
a gate of the backup selection control transistor serves as a backup word line port;
the main selection control transistor is connected between a second end of the main fuse and a source port;
the backup selection control transistor is connected between a second end of the backup fuse and the source port;
the second end of the backup fuse serves as a read port;
in a programming operation, the backup fuse and the main fuse form a parallel structure between the bit line port and the source port, the backup fuse and the main fuse being programmed independently;
in a read operation, the backup fuse and the main fuse form a series structure between the read port and the source port, the backup selection control transistor is disconnected, the main selection control transistor is conductive, and a read path comprises the series structure; and
when the main fuse is subjected to a programming failure, the main fuse has a failure resistance, the backup fuse has a backup programming resistance, a resistance of the series structure is the sum of the failure resistance and the backup programming resistance; and the magnitude of the backup programming resistance ensures that the resistance of the series structure is greater than a first threshold value which is a resistance threshold value for logic determination of the efuse unit that is in a programmed state.

2. The efuse memory according to claim 1, wherein the programming operation comprises a main programming operation in which the backup selection control transistor is disconnected and the main selection control transistor is conductive;
when the main fuse is subjected to normal programming, the main fuse has a main programming resistance after the main programming operation;
when the main fuse is subjected to a programming failure, the main fuse has a failure resistance after the main programming operation; and
the main fuse has a first initial resistance before the main programming operation.

3. The efuse memory according to claim 2, wherein the programming operation comprises a backup programming operation in which the backup selection control transistor is conductive and the main selection control transistor is disconnected;
the backup fuse has a backup programming resistance after the backup programming operation; and
the backup fuse has a second initial resistance before the backup programming operation.

4. The efuse memory according to claim 3, wherein in a read operation, when the main fuse is subjected to normal programming, the main fuse has the main programming resistance, the backup fuse has the second initial resistance, and a resistance of the series structure is the sum of the main programming resistance and the second initial resistance.

5. The efuse memory according to claim 4, wherein the first initial resistance is less than tens of ohms, the main programming resistance is greater than 100 k ohms, and the failure resistance is a few hundreds of ohms ˜2 k ohms.

6. The efuse memory according to claim 5, wherein the first threshold value is a few thousands of ohms;
the backup programming resistance is a few thousands of ohms;
the backup fuse is not flown after the backup programming operation; and
the programming current for the backup programming operation is less than that for the main programming operation; and the backup selection control transistor has a size smaller than that of the main selection control transistor.

7. The efuse memory according to claim 6, wherein the backup selection control transistor is NMOS and the main selection control transistor is NMOS; and
the source port is grounded.

8. The efuse memory according to claim 7, wherein the effuse memory further comprises an efuse array formed by connecting a plurality of the efuse units; and
in the efuse array:
the main word line ports of the efuse units in the same row are connected to the same main word line;
the backup word line ports of the efuse units in the same row are connected to the same backup word line;
the bit line ports of the efuse units in the same column are connected to the same bit line;
the read ports of the efuse units in the same column are connected to the same read line;
the bit lines are each connected to a power supply voltage by one power control transistor, the gate of the power control transistor being connected to a power supply control signal; and
the read lines are each connected to a one-position sensitive amplifier by one read control transistor, the gate of the read control transistor being connected to a read control signal.

9. The efuse memory according to claim 8, wherein when the main programming operation is performed on a selected efuse unit, the main word line of the selected efuse unit has a high level, the backup word line has a low level, the power control signal has a low level, and the read control signal has a low level;
when the backup programming operation is performed on the selected efuse unit, the main word line of the selected efuse unit has a low level, the backup word line has a high level, the power control signal has a low level, and the read control signal has a low level; and
when a read operation is performed on the selected efuse unit, the main word line of the selected efuse unit has a high level, the backup word line has a low level, the power control signal has a high level, the read control signal has a high level, and the sensitive amplifiers at respective positions operate.

10. A method for operating an efuse memory, wherein the efuse memory comprises: an efuse unit;
the efuse unit comprises a main fuse, a backup fuse, a main selection control transistor, and a backup selection control transistor;
a first end of the main fuse and a first end of the backup fuse are connected and serve as a bit line port;
a gate of the main selection control transistor serves as a main word line port;
a gate of the backup selection control transistor serves as a backup word line port;
the main selection control transistor is connected between a second end of the main fuse and a source port;
the backup selection control transistor is connected between a second end of the backup fuse and the source port; and
the second end of the backup fuse serves as a read port; and
the operation method comprises a programming operation in which the backup fuse and the main fuse form a parallel structure between the bit line port and the source port, the backup fuse and the main fuse being programmed independently, and a read operation in which the backup fuse and the main fuse form a series structure between the read port and the source port, the backup selection control transistor is disconnected, the main selection control transistor is conductive, and a read path comprises the series structure; and
when the main fuse is subjected to a programming failure, the main fuse has a failure resistance, the backup fuse is subjected to the programming operation and has a backup programming resistance, a resistance of the series structure is the sum of the failure resistance and the backup programming resistance; and the magnitude of the backup programming resistance ensures that the resistance of the series structure is greater than a first threshold value which is a resistance threshold value for logic determination of the efuse unit that is in a programmed state.

11. A method for operating an efuse memory according to claim 10, wherein the programming operation comprises a main programming operation in which the backup selection control transistor is disconnected, the main selection control transistor is conductive, and a programming current between the bit line port and the source port flows through the main fuse to realize programming of the main fuse;
when the main fuse is subjected to normal programming, the main fuse has a main programming resistance after the main programming operation;
when the main fuse is subjected to a programming failure, the main fuse has a failure resistance after the main programming operation; and
the main fuse has a first initial resistance before the main programming operation.

12. The method for operating an efuse memory according to claim 11, wherein when the main fuse is subjected to a programming failure, the programming operation further comprises performing a backup programming operation in which the backup selection control transistor is conductive, the main selection control transistor is disconnected, and a programming current between the bit line port and the source port flows through the backup fuse to achieve programming of the backup fuse;
the backup fuse has a backup programming resistance after the backup programming operation; and
the backup fuse has a second initial resistance before the backup programming operation.

13. A method for operating an efuse memory according to claim 12, wherein the programming operation does not perform the backup programming operation when the main fuse is subjected to normal programming;
in a read operation, when the main fuse is subjected to normal programming, the main fuse has the main programming resistance, the backup fuse has the second initial resistance, and a resistance of the series structure is the sum of the main programming resistance and the second initial resistance.

14. A method for operating an efuse memory according to claim 13, wherein the first initial resistance is less than tens of ohms, the main programming resistance is greater than 100 k ohms, and the failure resistance is a few hundreds of ohms ˜2 k ohms.

15. The method for operating an efuse memory according to claim 14, wherein the first threshold value is a few thousands of ohms;
the backup programming resistance is a few thousands of ohms;
the backup fuse is not flown after the backup programming operation; and
the programming current for the backup programming operation is less than that for the main programming operation; and the backup selection control transistor has a size smaller than that of the main selection control transistor.

16. The method for operating an efuse memory according to claim 15, wherein the backup selection control transistor is NMOS and the main selection control transistor is NMOS; and
the source port is grounded.

17. The method for operating an efuse memory according to claim 16, further comprising an efuse array formed by connecting a plurality of the efuse units; and
in the efuse array:
the main word line ports of the efuse units in the same row are connected to the same main word line;
the backup word line ports of the efuse units in the same row are connected to the same backup word line;
the bit line ports of the efuse units in the same column are connected to the same bit line;
the read ports of the efuse units in the same column are connected to the same read line;
the bit lines are each connected to a power supply voltage by one power control transistor, the gate of the power control transistor being connected to a power supply control signal; and
the read lines are each connected to a one-position sensitive amplifier by one read control transistor, the gate of the read control transistor being connected to a read control signal.

18. The method for operating an efuse memory according to claim 17, wherein when the main programming operation is performed on a selected efuse unit, the main word line of the selected efuse unit is applied with a high level, the backup word line is applied with a low level, the power supply control signal is applied with a low level, and the read control signal is applied with a low level;
when the backup programming operation is performed on the selected efuse unit, the main word line of the selected efuse unit is applied with a low level, the backup word line is applied with a high level, the power control signal is applied with a low level, and the read control signal is applied with a low level; and
when a read operation is performed on the selected efuse unit, the main word line of the selected efuse unit is applied with a high level, the backup word line is applied with a low level, the power control signal is applied with a high level, the read control signal is applied with a high level, and the sensitive amplifiers at respective positions operate.
